(19) United States
(12) Patent Application Publication
(10) Pub. No.: US 2005/0068077 A1
(43) Pub. Date: Mar. 31, 2005

(54) Local bias generator for adaptive forward body bias

(75) Inventors: James W. Tschanz, Portland, OR (US); Stephen H. Tang, Pleasanton, CA (US); Victor Zia, Beaverton, OR (US); Badarinath Kommandur, Hillsboro, OR (US); Siva G. Narendra, Portland, OR (US); Vivek K. De, Beaverton, OR (US)

Correspondence Address: FLESHNER & KIM, LLP, P.O. BOX 221200, CHANTILLY, VA, 20153, US

(73) Assignee: Intel Corporation

(21) Appl. No.: 10/673,283

(22) Filed: Sep. 30, 2003

(51) Int. Cl. H03L 7/06

(52) U.S. Cl. 327/158

(57) ABSTRACT

A local bias generator generates forward body bias that tracks variations in a supply voltage of a functional block containing one or more circuits having field-effect transistors. The bias is generated using a single-stage source-follower formed from a pair of matched transistors. In operation, the transistors convert a first bias signal into a second bias signal based on a difference between the supply voltage and a reference voltage. The first bias signal and reference voltage may be generated by a central bias generator.

### BACKGROUND OF THE INVENTION

1. Field of the Invention

This invention generally relates to signal generators, and more particularly to the generation of forward and/or reverse body bias signals for driving circuits including one or more transistors.

2. Description of the Related Art

Adaptive body bias can be used after fabrication to improve the bin split in a microprocessor and to reduce the variation in frequency and leakage caused by process variations. In performing adaptive body bias, a unique body bias voltage is set to maximize the frequency of the processor subject to leakage and total power constraints and the type of transistor technology in use. Body bias voltages may be applied to processors and other circuits that use PMOS transistors, NMOS transistors, or both.

Two types of body bias voltages are generally used to control the frequency of a microprocessor: forward body bias (FBB) voltage and reverse body bias (RBB) voltage. If forward body bias (FBB) is used, the frequency of the processor increases along with leakage. If reverse body bias (RBB) is applied, the frequency and leakage of the processor decreases. In some circuits, both forward and reverse body bias voltages are applied in order to compensate for process variations within the die. Parts of the circuit which are too slow receive forward body bias to increase their speed, while other parts which are faster than necessary receive reverse body bias to reduce their leakage power.

The circuitry required for applying adaptive body bias can be divided into two blocks: the central bias generator (CBG) and the local bias generators (LBG). The function of the central bias generator is to generate a reference voltage which is process, voltage, and temperature independent. This voltage represents the desired body bias to apply to transistors in the microprocessor core. If both PMOS and NMOS transistors are to be biased, two central bias generators may be used each generating a different reference voltage for each transistor type. Alternatively, a single central bias generator may be used which is capable of generating the reference voltages for both transistor types.

In contrast to the central bias generator, many local bias generators may be distributed throughout a processor die. The function of the local bias generators is to translate the reference voltage from the CBG into local block supply voltages and then drive these voltages to the transistors in each respective block. The purpose of the translation is to ensure that if a local block supply voltage changes, the body bias will change at the same time so that a constant bias is maintained.

Several designs have been proposed for local bias generators. The type and complexity required depends on whether forward body bias, reverse body bias, or both will be applied. If only forward bias is applied, the local body bias generator design shown in FIG. 1 may be used. This LBG includes two stages. The first stage includes a current mirror 1 which translates a reference voltage V_{REF} from a CBG (not shown) into a voltage V_{CC} referenced to a corresponding local block (also not shown). The second stage is a two-stage source-follower circuit 2 which provides the drive strength needed to supply body bias voltage V_{BP} to the local block. Ideally, the circuit is operated so that the output differential voltage (V_{CC}-V_{BP}) always equals the input differential voltage (V_{REF}-V_{Bias}).

The design shown in FIG. 1 is disadvantageous for many reasons. First, in terms of performance the circuit of FIG. 1 loses tracking as the input differential becomes small. This occurs because the transistors in the current mirror as well as the output stage fall out of saturation as the desired bias becomes smaller. Second, the multiple-circuit stages used to implement the local bias generator consume larger chip area and cause the generator to consume considerable static power.

Another local bias generator design includes an operational amplifier structure in a feedback configuration. This circuit operates from a higher supply voltage than the local block V_{CC} and is able to apply any bias value from forward body bias to reverse body bias. Tracking with the local V_{CC} is automatically performed through the feedback structure. While this circuit does not have all the drawbacks of the design shown in FIG. 1, its implementation consumes an even larger chip area and requires an even higher supply voltage for the amplifier. The second design may therefore be considered suitable for use only when both forward and reverse body bias needs to be applied.

### BRIEF DESCRIPTION OF THE DRAWINGS

FIG. 1 is a diagram showing one type of local bias generator which has been proposed.

FIG. 2 is a diagram showing a first embodiment of a bias generator in accordance with the present invention.

FIG. 3 is a diagram showing an example of a central bias generator that may be used to generate a reference signal V_{REF} in accordance with one or more embodiments of the present invention.

FIG. 4 is a diagram showing one possible configuration of a local bias generator in accordance with the first embodiment of the present invention. This local bias generator provides forward PMOS body bias using a single-stage, matched source-follower driver.

FIG. 5 is a graph showing results of a simulation performed for the local bias generator of FIG. 4 using exemplary values. In this graph, the output voltage V_{BP} tracks the input voltage V_{Bias} with a constant gate-to-source offset voltage V_{GS} for both transistors in the source-follower stage.

FIG. 6 is a graph showing additional results of the simulation performed for the local bias generator of FIG. 4 using exemplary values. In this graph, effective forward PMOS body bias is applied to the circuit (subtraction of V_{BP} from V_{CC}) within a range of between 0.5 V and 0.05 V.

FIG. 7 is a graph showing results of another simulation performed for the single-stage source-follower embodiment of the present invention, under conditions where the local supply voltage V_{CC} changes.

FIG. 8 is diagram showing a local bias generator in accordance with a second embodiment, in which NMOS transistors in a dual-well configuration are used to provide forward body bias.

FIG. 9 is diagram showing a local bias generator in accordance with a third embodiment, in which NMOS transistors in a triple-well configuration are used to provide forward body bias.

FIG. 10 is a diagram showing a processing system which may include one or more of the embodiments of bias generator of the present invention.

### DESCRIPTION OF THE PREFERRED EMBODIMENTS

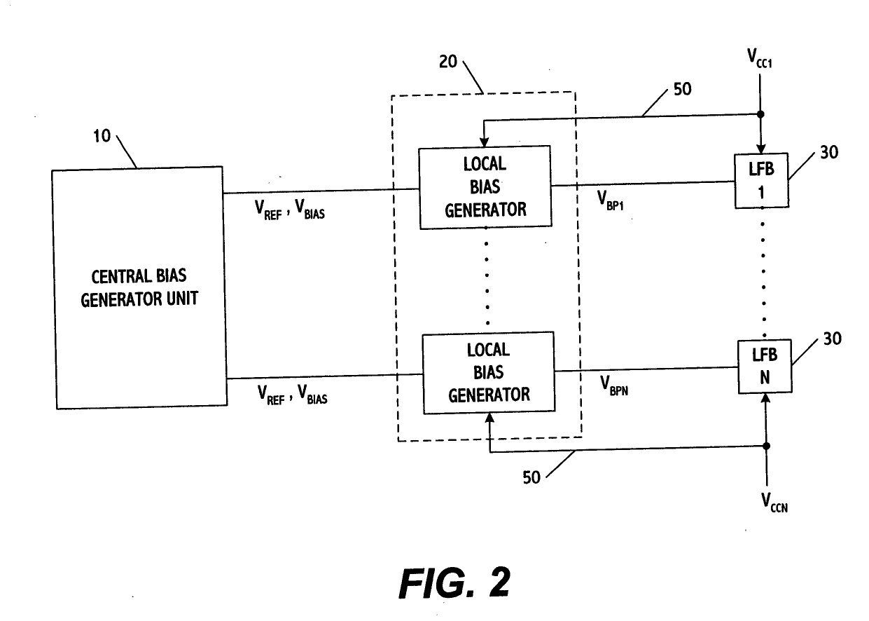

Referring to FIG. 2, a bias generator in accordance with a first embodiment of the present invention includes a central bias generator unit 10 and a local bias generator unit 20, the latter of which may be coupled to one or more circuits 30 located on or off the same chip on which the generator units are located. These circuits, generally referred to as local functional blocks, include one or more transistors which operate as switches or amplifiers or perform any other function required. The local functional blocks may be connected to one another such that the output of one block serves as the input into one or more other blocks, the blocks may be separately situated to generate signals for performing independent tasks, or a combination of the two is possible.

The central bias generator unit performs the function of generating reference and bias voltages which are used in deriving local biasing voltages for each of the functional blocks. These voltages are preferably generated in a manner which is process, voltage, and temperature independent.

Structurally, the central bias generator may be any type known and is preferably configured to generate one or more reference and body bias voltages based on the requirements of the intended application of the chip or host system and the type of transistor technology used in the local functional blocks. If both PMOS and NMOS transistors are included in the local functional blocks, then unit 10 may include two central bias generators each generating a separate reference voltage for the PMOS and NMOS transistors. Alternatively, one central bias generator capable of generating separate reference voltages for the transistor types may be used. In terms of relative placement, the central bias generator unit may be located on the same chip as the local bias generators or the CBG may be located off-chip.

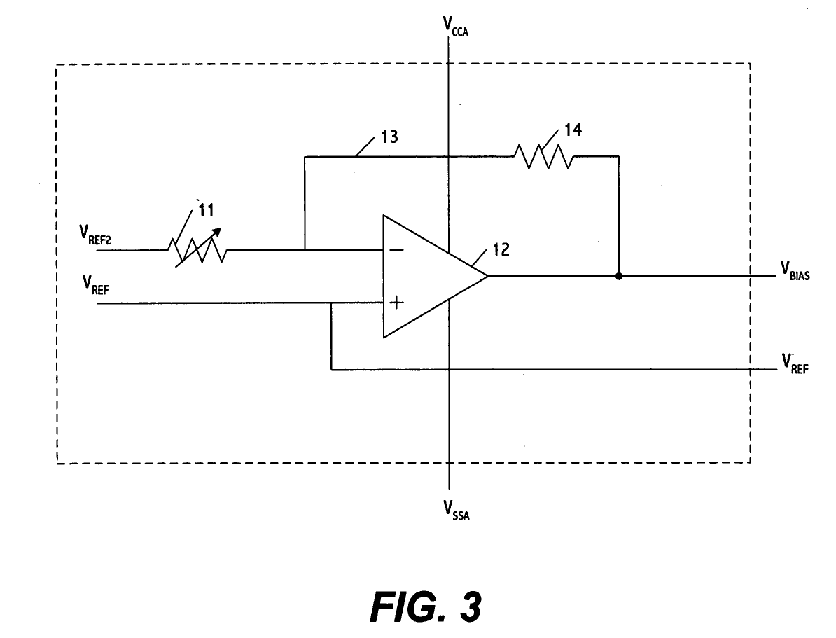

FIG. 3 shows an example of a central bias generator that may be included in the CBG unit. This generator includes a variable resistor 11, an operational amplifier 12, and a feedback path 13 that includes a resistor 14. The variable resistor may, for example, be formed from an R-2R resistor network connected to input a variable reference voltage VREF2 into the inverting terminal of the amplifier. A fixed reference voltage V_{REF} is input into the non-inverting terminal. The amplifier is driven by supply voltages V_{CCA} and V_{SSA}. The feedback path includes a resistor 14 which determines the output bias voltage in combination with the variable resistor in accordance with the following equation: V_{Bias}=V_{Ref2}−(R_{fbk}/Rᵥₐᵣ)(V_{Ref2}−V_{ref}), where R_{fbk}/Rᵥₐᵣ is the ratio of the feedback and variable resistances.

In operation, the output of the variable resistor sets the bias voltage V_{Bias} generated by the CBG unit. As this resistance changes, the bias voltage changes relative to the fixed reference voltage. The bias and reference voltages are then output to the local bias generators as shown in FIG. 2. Those skilled in the art can appreciate that the circuit of FIG. 2 merely illustrates one possible configuration of a central bias generator that may be included in unit 10, and that other types of CBGs may be used depending on the particular requirements of the intended application.

The local bias generator unit includes one or more local bias generators, each of which includes a single-stage circuit which operates to ensure that a constant bias is supplied to a respective one of the local functional blocks (LFBs). This constant bias is supplied by adjusting the output of each single-stage circuit to follow variations in the supply voltage of a corresponding one of the local functional blocks.

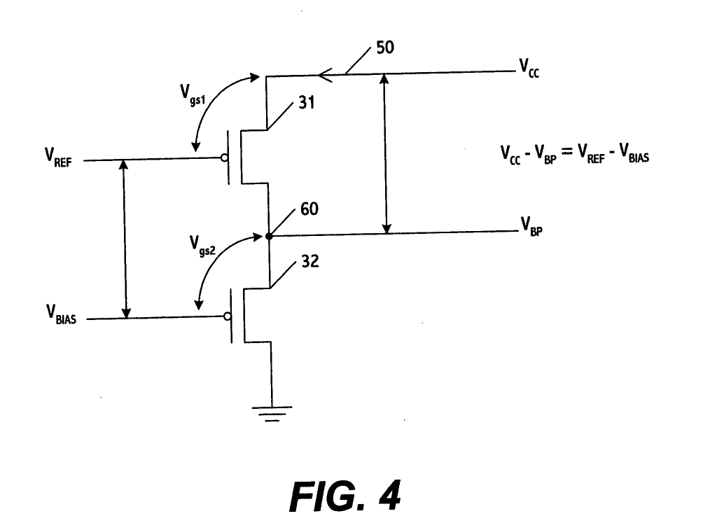

FIG. 4 shows one configuration of a local bias generator that may be included in unit 20. This generator includes an amplifier which preferably has unity gain and generates an output signal that “follows” its input signal. In the embodiment shown, the amplifier is in the form of a single-stage source-follower (buffer) circuit. This circuit includes two FET transistors 31 and 32. The drain of transistor 31 is connected to the source of transistor 32, the drain of transistor 32 is connected to a reference potential, and the gates of the transistors respectively receive the reference and bias voltages V_{REF} and V_{Bias} output from the central bias generator unit. The reference potential may be ground or some other value.

Each local functional block is powered by a respective supply voltage V_{CC1} through V_{CCN}, where N equals the number of functional blocks. These supply voltages are input into corresponding ones of the local bias generators along a signal line 50, which is connected to the source of transistor 31. A node 60 outputs a bias voltage V_{BP} which has been advantageously adjusted to track any change in the local supply voltage V_{CC} input along signal line 50. The single-stage source-follower thus may be said to provide adaptive body bias because it constantly adjusts bias voltage V_{BP} to track variations in V_{CC}.

The local bias generator employs two techniques to improve tracking and reduce complexity over other LBG circuits which have been proposed. The first technique involves performing a level-shifting function with respect to the output of the central bias generator unit. The second technique involves matching the transistors in the local bias generator. Both techniques are described in greater detail in the discussion which follows.

The first technique involves designing each local bias generator so that it shifts the level of the bias voltage V_{Bias} output from the central bias unit. This shifting (or level-translation) function is an inherent function of the single-stage source-follower circuit, i.e., the single-stage circuit shifts the output voltage of the generator relative to its input voltage. The amount V_{BP} is shifted is proportional to changes that occur in supply voltage V_{CC} input into a corresponding local functional block. The changes in V_{CC} are measured relative to the reference voltage V_{REF} output from the central bias generator. The local bias generator therefore shifts the input bias voltage V_{Bias} by an amount equal to a difference between V_{CC} and V_{REF}. This may be illustrated as follows.

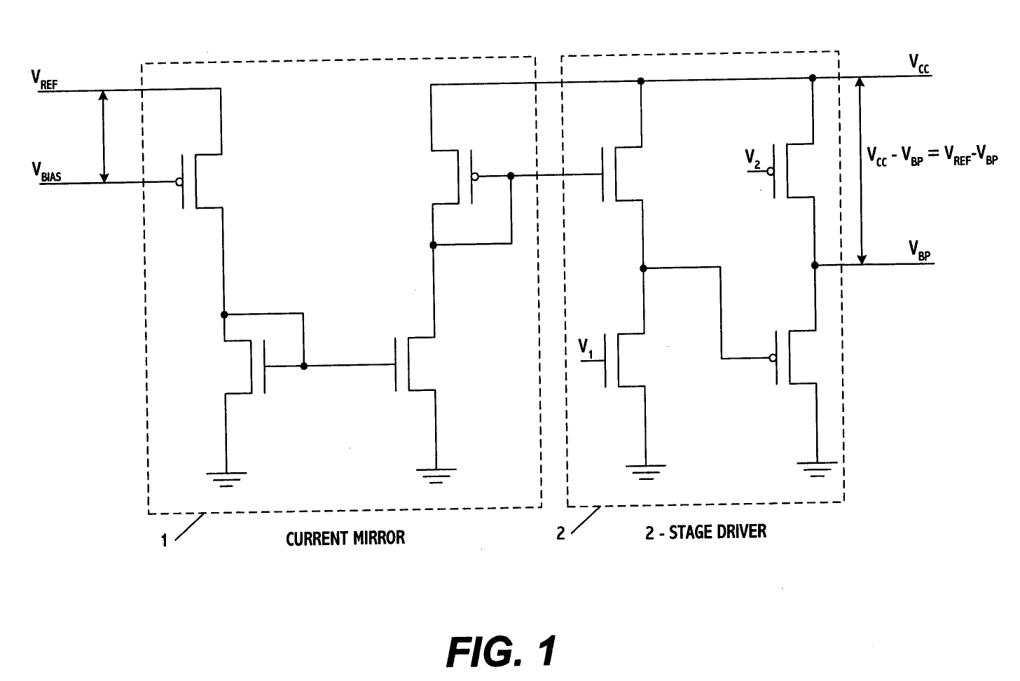

Consider the case where the input bias voltage V_{Bias} is 0.4 V. If V_{CC} is 1.2 V and V_{REF} is 0.9 V, the difference is 0.3V. The local bias generator operates to translate the input bias voltage by 0.3 V, thereby making the output bias voltage V_{BP} equal to 0.7 V. The local bias generator thus automatically shifts the output bias voltage to follow changes in a corresponding LFB supply voltage. This function is accomplished using a much simpler design than other proposed circuits such as shown in FIG. 1.

The second technique involves making both transistors in the single source-follower stage identical in size in terms of their channel widths and channel lengths. By matching these characteristics, both transistors will have the same or substantially the same current flowing through them, assuming the load current is much smaller than the bias current in the source-follower. (The load current is defined by the circuit connected to the output bias voltage V_{BP}, which, for example, a corresponding one of the local functional blocks. The output bias voltage may go to the body connections (e.g,. the N-wells) of the PMOS transistors in the block. The current in this connection is typically very low unless a large amount of forward body bias is applied. As the forward body bias increases, the diodes formed by the source/drain of the PMOS transistors and the body can become forward-biased. This will cause current to flow from V_{CC}, out of the body, and through the local bias generator in the terminal V_{BP}. Preferably, the local bias generator is constructed so that this current is small compared with the static current flowing from V_{CC}, through the matched transistors in the LBG, to ground.) Because the transistors in the source-follower are matched and thus have the same current flowing through them, the gate-to-source voltages V_{GS1} and V_{GS2} of these transistors are the same. As a result, any variation in local supply voltage V_{CC} will cause the gate-to-source voltage of transistor 30 to change by the same amount (since the reference voltage V_{REF} output from the central bias generator is constant). This causes a corresponding change in the gate-to-source voltage of transistor 40, which changes the output bias voltage V_{BP} by the same amount.

By matching the transistors in the single-stage source-follower and then operating them so that they remain in saturation, the output bias voltage V_{BP} will track any variations in the local reference voltage V_{CC} without requiring, for example, use of a current mirror stage or a second source-follower stage as shown in the circuit of FIG. 1. Other advantages are also evident. For example, because the local bias generator can be realized using only one source-follower stage, a significant reduction in chip area required to implement one or more embodiments of the bias generator of the present invention may be achieved.

Also, an improvement in the operating range of the generator over other proposed techniques is possible. This improvement in range is at least directly attributable the reduction in the number of source-follower stages in the local bias generator. This performance enhancement can be seen in comparison with the circuit of FIG. 1. In this circuit, for example, as body bias becomes small (e.g., below 100 mV), the transistors in each of the two source-follower stages fall out of saturation and consequently adversely affect the tracking of the LBG. By eliminating two of the three stages, namely the current-mirror stage and one of the source-follower stages, the local bias generator in accordance with the first embodiment of the present invention is able to achieve a significant improvement in tracking.

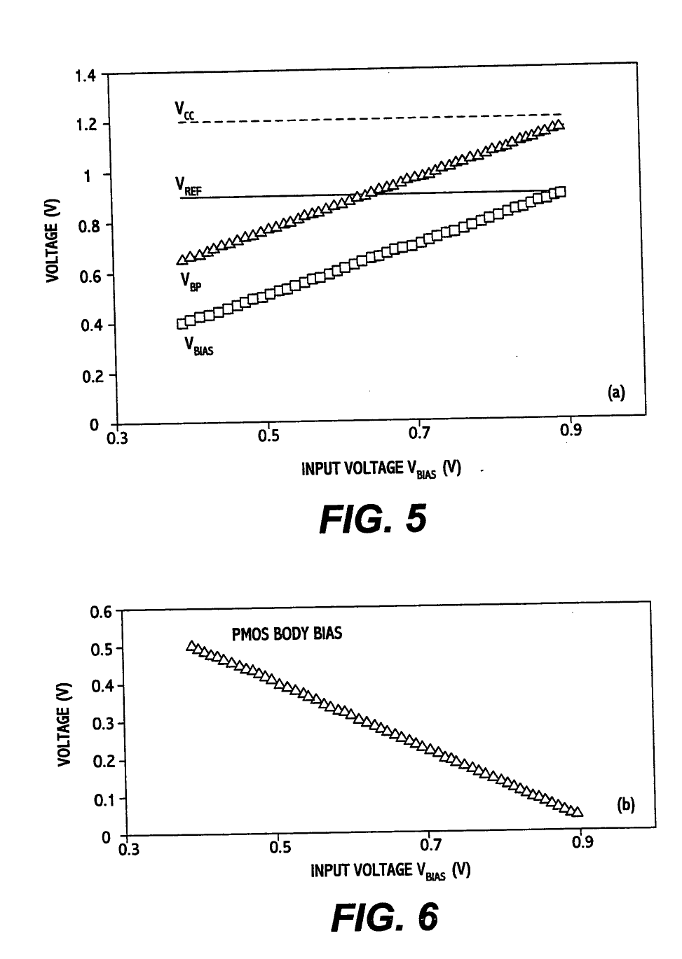

FIG. 5 is a graph which shows a non-limiting example of this improved performance, achieved during a simulation of the single-stage source-follower circuit of FIG. 4. The graph shows that the output body bias voltage V_{BP} tracked the input bias voltage V_{Bias} with a constant gate-to-source voltage V_{GS} offset. In performing the simulation, the following exemplary values were used: the local reference voltage V_{CC} was fixed at 1.2 V and the input bias voltage was changed from 0.4 V to 0.9 V. The LBG was designed to shift the input bias voltage up by 0.3 V, so the output bias signal V_{Bias} went from 0.7 V to 1.2V which represents a PMOS body bias of 0.5 V to 0 V. As shown in the graph, the LBG applied the correct bias voltage all the way until the output reached 1.15 V. At that point, the output voltage became saturated.

FIG. 6 is a graph showing the effective forward body bias applied to the PMOS transistors in the local bias generator during the simulation. As shown, this forward body bias ranged from 0.5 V to 0.05V, which is a larger range than can be achieved by the two-stage source-follower circuit of FIG. 1.

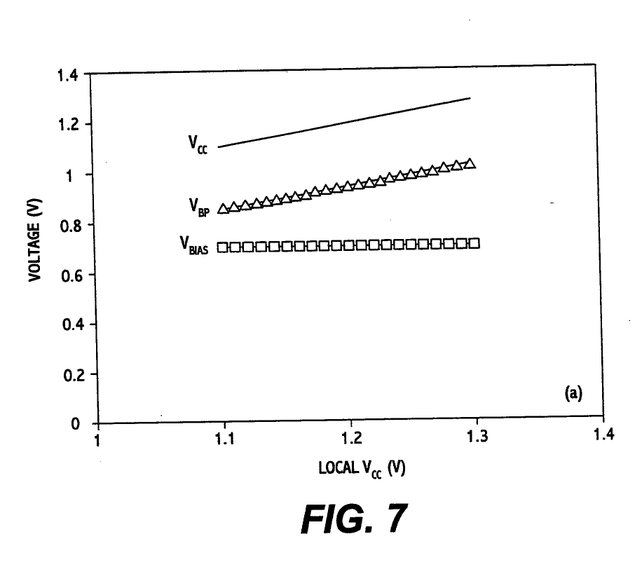

FIG. 7 is a graph showing results of another simulation performed for the single-stage source-follower embodiment of the present invention. This simulation was performed under conditions where the local supply voltage V_{CC} changed. In order to maintain a constant body bias, the graph shows that the output body bias voltage V_{BP} tracked changes in the local supply voltage V_{CC}. More specifically, in the simulation the local V_{CC} varied from 1.1 V to 1.3 V and the bias voltage tracked this change so that a constant 200 mV forward body bias is maintained.

The changes in V_{CC} in the graph of FIG. 7 may result from a variety of factors including the activity level of the circuit. For example, if the circuit is very active (many transistors are switching), a large flow of current would form in the power grid. This creates a large resistance in the grid that generates a corresponding voltage drop. As a result, the local V_{CC} value may become lower than a V_{CC} value that would be achieved when the circuit is in quiet or standby mode. Because different areas of chip die have different activity levels, each block may have a different voltage on its V_{CC} grid.

A bias generator in accordance with a second embodiment of the present invention includes a central bias generator and one or more local bias generators, the latter of which may be coupled to one or more circuits local functional blocks. The central bias generator and local functional blocks may be the same ones used in the first embodiment as shown in FIG. 2, but the local bias generators are different in that each generates NMOS body bias to a corresponding local functional block. That is, the local bias generators bias the NMOS transistors in corresponding LFBs, while the first embodiment applied PMOS body bias.

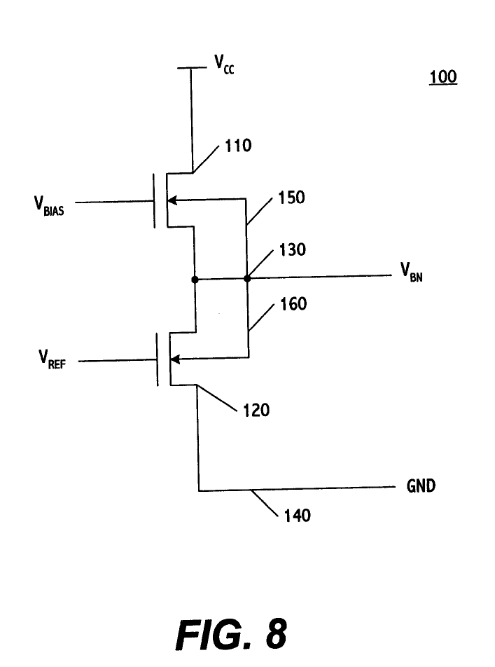

FIG. 8 shows a preferred structure of the local bias generator in accordance with the second embodiment. Like in the first embodiment, LBG 100 is implemented as a single source-follower stage. However, instead of using PMOS transistors, the single stage of the second embodiment includes two NMOS transistors 110 and 120, where the source of transistor 110 is connected to a drain of transistor 120 and the gates of these transistors respectively receive the bias and reference voltages V_{Bias} and V_{REF} output from the central bias generator. A drain of transistor 110 is connected to a supply potential V_{CC} and a source of transistor 120 is connected to a reference potential which, for example, may be ground. A node 130 between the transistors outputs the forward body bias voltage V_{BN} and a signal line 140 connected to the drain of transistor 120 provides the reference potential (illustrative shown as GND) to one or more local functional blocks.

The NMOS transistors may be arranged to have a dual-well configuration (evident from arrows 150 and 160) in which both transistors share the same substrate. In this configuration, it is not possible to locally tie the transistor body to the source. As a result, for the NMOS bias implementation of FIG. 8, the top transistor 110 has zero body bias while the bottom transistor 120 receives a varying forward bias as the output voltage changes. (The dual-well configuration is common for NMOS transistors because its manufacturing process is less expensive to implement than a triple-well process. If desired, however, from a performance standpoint the NMOS transistors may have a triple-well configuration or any other configuration known.) In spite of their structural differences, the local bias generator of the second embodiment can achieve at least the same level of improved performance as the first embodiment.

A bias generator in accordance with a third embodiment of the present invention includes a central bias generator and one or more local bias generators, the latter of which may be coupled to one or more circuits local functional blocks. The central bias generator and local functional blocks may be the same ones used in the first embodiment as shown in FIG. 2, but again the local bias generator is different.

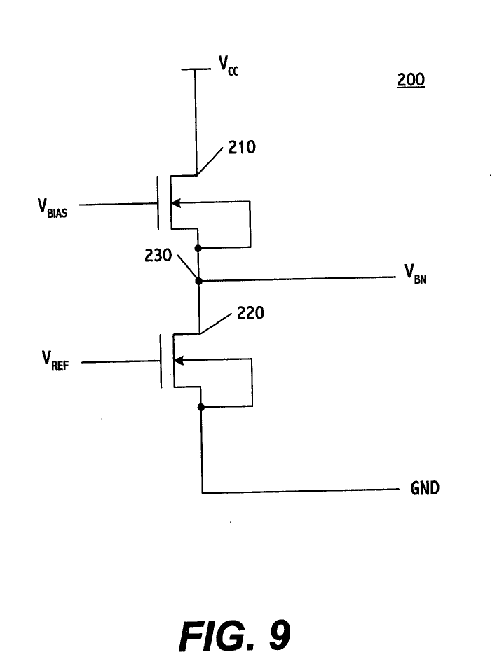

FIG. 9 shows a preferred structure of the local bias generator in accordance with the third embodiment. This generator 200 is implemented as a single source-follower stage using NMOS transistors 210 and 220 and an intermediate node 230 for outputting the level-shifted bias voltage V_{BN}. Unlike the FIG. 8 embodiment, a triple-well process is used to construct the NMOS transistors and the body connections of these transistors are tied locally their sources. In spite of these differences, the local bias generator of the third embodiment can achieve at least the same level of improved performance as the first and second embodiments.

In the foregoing embodiments, the local bias generator provides forward body bias to one or more local functional blocks. Those skilled in the art can appreciate that, if desired, the local bias generator may be designed to provide reverse body bias or both forward and reverse body bias if the functional blocks and/or application requirements so require.

The local functional blocks include groups of circuitry (on one or more IC dies) designed to impart a certain logic or mixed signal (analog/digital) functionality to the electrical system embodied within or including generator units. The blocks may be manufactured, for example, using an entirely MOS process in which all of the active devices are FETs, a Bipolar-MOS process in which other transistors in addition to FETs are also provided. The MOS process may involve the use of only PMOS or NMOS transistors, or a CMOS process may be implemented in which both transistor types are used. In general, there is some flexibility in the physical placement of the CBG, LBGs, and FUBs. In most advanced CMOS ICs, however, all three components are most likely to be formed on the same IC die for lower cost and better performance. In FIG. 1, a plurality of blocks are shown. However, if desired, one or more embodiments of the bias generator of the present invention may be used to bias and drive only one functional unit block if desired.

The functional unit blocks may, for example, include any one or more of the following types of circuits: adders, multipliers, register files, cache memory blocks, control logic, analog blocks such as phase-locked loops, clock generators, and sense amplifiers to name a few, as well as any other type of circuit that may be included in a local functional block on a circuit die.

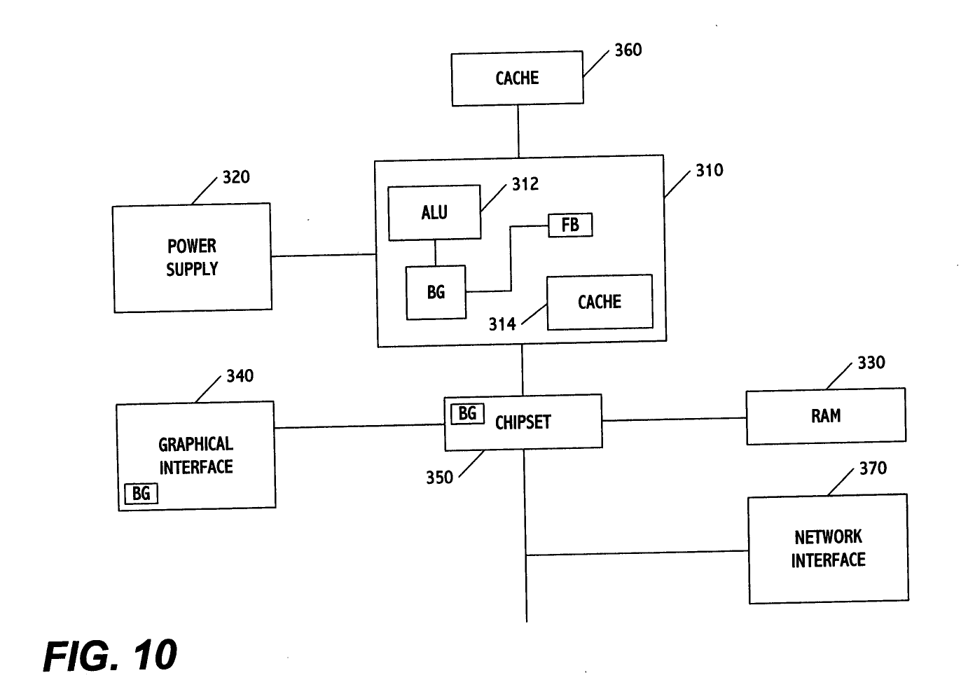

FIG. 10 shows a processing system which includes a processor 310, a power supply 320, and a memory 330 which, for example, may be a random-access memory. The processor may include an arithmetic logic unit 312 and an internal cache 314. In addition, the system may include a graphical interface 340, a chipset 350, a cache 360 and a network interface 370. A bias generator BG in accordance with one or more embodiments of the present invention may be included to provide forward or reverse body bias, or both, to any of the circuits of the processing system. For example, the generator may be used to control an operating frequency of the processor or in more local terms may be used to control a reference signal supplied to any of the internal circuits (e.g., functional block FB) of the processor or any circuit coupled thereto.

In the foregoing embodiments, the term “central” is used in connection with the central bias generator only in the sense that an output of the CBG may be distributed to provide forward or reverse body bias, or both, via one or more of the local bias generators, to a number of transistors in the local functional block(s).

One or more of the foregoing embodiments of the bias generator of the present invention outperforms other bias generators which have been proposed in a number of ways. For example, other bias generators cannot track a reference voltage over a sufficiently large operating range. In contrast, the embodiments presented herein have ability to closely track, for example, changes in block supply voltage down to small bias values. This improved performance may be attributed, in at least one respect, to the use of a single-stage source-follower circuit which, for example, demonstrates better tracking than the two-stage source-follower design shown in FIG. 1.

Another difference lies in power and chip-area requirements. The bias generator of FIG. 1 and others which have been proposed require high supply voltages for their operation and are of a size which consumes a large chip area. In contrast, through the use of its single-stage source-follower the embodiments presented herein consume significantly less chip area. Also, the additional supply voltage which other bias generators use is not a requirement in the single-stage source-follower.

As process variations increase, these improvements in providing adaptive body bias become an effective way of increasing the number of high-bin parts and recovering parts that fail F_{MAX} or I_{SB} (leakage) constraints. In order to efficiently implement adaptive body bias, local bias generators are needed which do not consume significant chip area or power, while simultaneously achieving an improved level of performance. The one or more embodiments of the bias generator of the present invention provide all of these advantages while avoiding the disadvantages of other bias generators which have been proposed. This makes applying body bias faster and more efficient to implement and thus highly desirable from a chip designers standpoint.

Also, in one or more of the foregoing embodiments, the central bias generator may direclty output a shifted version of the reference voltage, so when it is shifted again by the source-follower the levels are correct. This is one reason why a two-stage follower circuit is not required, which may be understood as follows.

In a conventional central bias generator the reference voltage is usually the same as the local block ground or V_{CC}, and the bias voltage is the same as the final desired body voltage. For example, assume PMOS body bias where V_{CC} is 1.2V. In a conventional CBG implementation, the reference voltage would be 1.2V and the bias voltage would range from 1.2 V (ZBB) to 0.7V (500 m V FBB). The conventioal local bias generator would then translate this to the local block V_{CC} using a two-stage source follower, and the final body voltage would again be 1.2V to 0.7V.

In one or more embodiments of the present invention, however, the reference voltage may be shifted from V_{CC}. In the above example, the reference voltage would be 0.9 V and the bias voltage would lie in a range from 0.9V to 0.4V. The local bias generator then shifts this up to the final value of 0.7V to 1.2V. So, the CBG output in these embodiments may be considered to be “pre-shifted” so that the local bias generator shifts it back to the appropriate level.

Other modifications and variations of the foregoing embodiments of the present invention will be apparent to those skilled in the art from the foregoing disclosure. Thus, while only certain embodiments of the invention have been specifically described herein, it will be apparent that numerous modifications may be made thereto without departing from the spirit and scope of the invention.

1. A bias generator, comprising:
a first node to receive a supply voltage; and
a single-stage source-follower to generate body bias for a local functional block based on a variation in the supply voltage received from the first node.

2. The bias generator of claim 1, wherein the single-stage source-follower includes: first and second matched transistors to convert a first bias voltage into a second bias voltage based the supply voltage variation.

3. The bias generator of claim 2, further comprising:
a second node coupled between the first and second matched transistors, the second node outputting the second bias voltage as said body bias to the local functional block.

4. The bias generator of claim 3, wherein the first node is connected to a source of the first transistor, the second node is connected to a drain of the first transistor and a source of the second transistor, and gates of the first and second transistors are respectively connected to receive the first bias voltage and a reference voltage.

5. The bias generator of claim 4, wherein the single-stage source-follower converts the first bias voltage into the second bias voltage based on a difference between the supply voltage and the reference voltage.

6. The bias generator of claim 1, wherein the supply voltage is a supply voltage of the local functional block.

7. The bias generator of claim 1, wherein said body bias is NMOS body bias.

8. The bias generator of claim 1, wherein said body bias is PMOS body bias.

9. A circuit, comprising:
a central bias generator to generate a first bias voltage; and
a local bias generator including:
(a) a first node to receive a supply voltage, and
(b) a single-stage source-follower to convert the first bias voltage into a second bias voltage based on a variation in the supply voltage received from the first node.

10. The circuit of claim 9, wherein the single-stage source follower provides the second bias voltage as forward body bias to a local functional block.

11. The circuit of claim 10, wherein the supply voltage is a supply voltage of the local functional block.

12. The circuit of claim 9, wherein the single-stage source-follower includes:
first and second matched transistors that convert the first bias voltage into the second bias voltage based the supply voltage variation.

13. The circuit of claim 12, further comprising:
a second node coupled between the first and second matched transistors, the second node outputting the second bias voltage as forward body bias to a local functional block.

14. The circuit of claim 13, wherein the first node is connected to a source of the first transistor, the second node is connected to a drain of the first transistor and a source of the second transistor, and gates of the first and second transistors are respectively connected to receive the first bias voltage and a reference voltage.

15. The circuit of claim 14, wherein the single-stage source-follower converts the first bias voltage into the second bias voltage based on a difference between the supply voltage and the reference voltage.

16. The circuit of claim 14, wherein the central bias generator outputs the reference voltage.

17. The circuit of claim 16, wherein the central bias generator outputs the reference voltage as a shifted value.

18. The circuit of claim 9, wherein the second bias voltage provides NMOS forward body bias to a local functional block.

19. The circuit of claim 9, wherein the second bias voltage provides PMOS forward body bias to a local functional block.

20. A method, comprising:
receiving a supply voltage of a local functional block; and
generating body bias for the local functional block from a single-stage source-follower based on a variation in the supply voltage.

21. The method of claim 20, wherein generating the body bias includes: converting a first bias voltage into a second bias voltage based on the supply voltage variation, said single-stage source-follower performing the conversion using first and second matched transistors.

22. The method of claim 20, wherein said converting includes:
converting the first bias voltage into the second bias voltage based on a difference between the supply voltage and a reference voltage.

23. The method of claim 20, wherein said body bias is NMOS body bias.

24. The method of claim 20, wherein said body bias is PMOS body bias.

25. A processing system, comprising:
a functional block;
a central bias generator to generate a first bias voltage; and
a local bias generator including:
(a) a first node to receive a supply voltage of the functional block, and
(b) a single-stage source-follower to convert the first bias voltage into a second bias voltage based on a variation in the supply voltage of the functional block.

26. The system of claim 25, wherein the single-stage source follower provides the second bias voltage as forward body bias to the functional block.

27. The system of claim 25, wherein the single-stage source-follower includes:
a second node; and
first and second matched transistors coupled to the second node, the first and second matched transistors convert the first bias voltage into the second bias voltage based the supply voltage variation.

28. The system of claim 27, wherein the first node is connected to a source of the first transistor, the second node is connected to a drain of the first transistor and a source of the second transistor, and gates of the first and second transistors are respectively connected to receive the first bias voltage and a reference voltage.

29. The system of claim 28, wherein the single-stage source-follower converts the first bias voltage into the second bias voltage based on a difference between the supply voltage and the reference voltage.

30. The system of claim 29, wherein the central bias generator outputs the reference voltage.

31. The bias generator of claim 25, wherein the supply voltage is a supply voltage of the local functional block.

32. The bias generator of claim 31, wherein the source-follower adjusts the body bias to track variations in the supply voltage.

33. The bias generator of claim 31, wherein the source-follower continuously adjusts the body bias to track variations in the supply voltage.

34. The bias generator of claim 31, wherein the source-follower automatically shifts a level of the body bias to follow changes in the supply voltage of the local functional block.

35. The bias generator of claim 34, wherein the source-follower shifts the level of the body bias based on a difference between the supply voltage and a reference voltage.

36. The bias generator of claim 2, wherein the first and second transistors have a same channel length and a same channel width.

37. The bias generator of claim 36, wherein the first and second transistors are both operated in saturation.

38. The bias generator of claim 2, wherein a same current flows through the first and second transistors.

39. The circuit of claim 9, wherein the supply voltage is a supply voltage of a local functional block which operates based on the second bias voltage.

40. The circuit of claim 39, wherein the source-follower converts the first bias voltage into the second bias voltage so that the second bias voltage track variations in the supply voltage.

41. The circuit of claim 9, wherein the source-follower converts the first bias voltage into the second bias voltage based on a difference between the supply voltage and a reference voltage.

42. The circuit of claim 12, wherein the first and second transistors have a same channel length and a same channel width.

43. The circuit of claim 42, wherein the first and second transistors are both operated in saturation.

44. The circuit of claim 12, wherein a same current flows through the first and second transistors.

45. The method of claim 20, wherein a source-follower adjusts the body bias to track variations in the supply voltage.

46. The method of claim 45, wherein the source-follower continuously adjusts the body bias to track variations in the supply voltage.

47. The method of claim 20, wherein generating the body bias includes:
automatically shifting a level of the body bias to follow changes in the supply voltage of the local functional block.

48. The method of claim 47, wherein the level of the body bias is shifted based on a difference between the supply voltage and a reference voltage.
